(19) United States
(12) Patent Application Publication
(10) Pub. No.: US 2024/0282722 A1
(43) Pub. Date: Aug. 22, 2024

(54) BALL GRID ARRAY RF PACKAGE CONFIGURATIONS

(71) Applicant: Infinera Corporation, San Jose, CA (US)

(72) Inventors: John W. Osenbach, Kutztown, PA (US); Jiaming Zhang, Macungie, PA (US); Li Li, San Jose, CA (US); Thomas Gregorich, San Diego, CA (US)

(73) Assignee: Infinera Corporation, San Jose, CA (US)

(21) Appl. No.: 18/112,494

(22) Filed: Feb. 21, 2023

(51) Int. Cl. H01L 23/64; H01L 23/00; H01L 23/31; H01L 23/367; H01L 23/498

(52) U.S. Cl. CPC H01L 23/642; H01L 23/3128; H01L 23/367; H01L 23/49811; H01L 23/49822; H01L 23/49838; H01L 23/562

(57) ABSTRACT

Consistent with an aspect of the present disclosure, a flexible electrical interconnect connects a transmit receive optical subassembly (TROSA) with an integrated circuit package via a transmission line provided on a surface of a substrate upon which the integrated circuit is provided. Alternatively, the transmission line is embedded in the substrate. Mechanisms are provided to mechanically balance temperature induced stresses within the substrate and keep the substrate substantially planar and thus minimize damage to the integrated circuit and/or the electrical connections thereto.

The present patent application hereby claims priority to the provisional patent application identified by U.S. Ser. No. 63/311,725 filed on Feb. 18, 2022, the entire content of which is hereby incorporated by reference.

### BACKGROUND

Optical communication systems transmit and receive optical signals that carry data at rates in excess of 400 Gbit/second. In one example, transceiver modules both transmit optical signals on a first fiber and receive optical signals on a second fiber. In a further example, client data is provided to the module, which is then processed by an integrated circuit, which supplies corresponding analog signals to a driver circuit. The driver circuit, in turn, provides drive signals to a modulator that outputs a modulated optical signal associated with the client data.

The transceiver module also includes photodiodes that detect the incoming optical signals on the second fiber. In one example, The photodiodes generate electrical signals which are amplified by transimpedance amplifiers (TIAs), and the amplified electrical signals are supplied to the same or a different integrated circuit than that noted above, which outputs client data from the module.

The electrical signals input to and output from the integrated circuit have frequencies that increase with increasing data rates. At such high frequencies, such as frequencies greater than 90 GHZ, discontinuities in the wiring or traces carrying the electrical signals through a substrate upon the integrated circuit is bonded can create reflections. Such reflections can increase the impedance of the traces and create loss, which may also be considered an insertion loss. Moreover, the reflections may create errors in the received data.

### SUMMARY

Consistent with an aspect of the present disclosure, a flexible electrical interconnect connects a transmit receive optical subassembly (TROSA) with an integrated circuit package via a transmission line provided on a surface of a substrate upon which the integrated circuit is provided. Alternatively, the transmission line is embedded in the substrate. Mechanisms are provided to mechanically balance temperature induced stresses within the substrate and keep the substrate substantially planar and thus minimize damage to the integrated circuit and/or the electrical connections thereto.

It is to be understood that both the foregoing general description and the following detailed description are exemplary and explanatory only and are not restrictive of the invention, as claimed.

The accompanying drawings, which are incorporated in and constitute a part of this specification, illustrate one (several) embodiment(s) and together with the description, serve to explain the principles of the invention.

### BRIEF DESCRIPTION OF THE DRAWINGS

FIG. 1 shows an example of a module consistent with the present disclosure;

FIG. 2 shows a cross-sectional view of an integrated circuit (IC) package consistent with an aspect of the present disclosure;

FIG. 3 shows a cross-sectional view of an IC package consistent with an additional aspect of the present disclosure;

FIG. 4 shows a cross-sectional view of an IC package consistent with a further aspect of the present disclosure;

FIG. 5 shows a cross-sectional view of an IC package consistent with an additional aspect of the present disclosure;

FIG. 6 shows a cross-sectional view of an IC package consistent with another aspect of the present disclosure;

FIG. 7 shows a cross-sectional view of an IC package consistent with a further aspect of the present disclosure;

FIG. 8 shows a cross-sectional view of an IC package consistent with another aspect of the present disclosure; and

FIG. 9 shows a plan view of the IC package shown in FIG. 8.

### DESCRIPTION OF THE EMBODIMENTS

Consistent with an aspect of the present disclosure, a flexible interconnect, including a plurality of conductors provided on a flexible substrate, connects a TROSA with an integrated circuit in a ball grid array (BGA) package. The integrated circuit is provided on a substrate which includes multiple layer whereby conductive traces may be provided between adjacent layers of the substrate to provide electrical connections to the integrated circuit in addition to the flexible interconnect. The traces, however, are not provided in a region of the substrate adjacent to a transmission line that connects the flexible interconnect with the integrated circuit. Accordingly, in one example, a mold compound may be provided over the substrate having a higher thermal expansion coefficient and stiffness than the integrated circuit so as to balance thermal generated stress in the substrate when the temperature of the integrated circuit increases. Such stresses would otherwise be created in the substrate as a result of the portion of the substrate adjacent the transmission line having fewer conductors than a portion of the substrate near the integrated circuit. Such asymmetry can cause the substate to be mechanically unstable when the integrated circuit operates at high temperatures.

In another example, a lid is attached to the substrate to provide similar mechanical stability.

Reference will now be made in detail to the present exemplary embodiments of the present disclosure, which are illustrated in the accompanying drawings. Wherever possible, the same reference numbers will be used throughout the drawings to refer to the same or like parts.

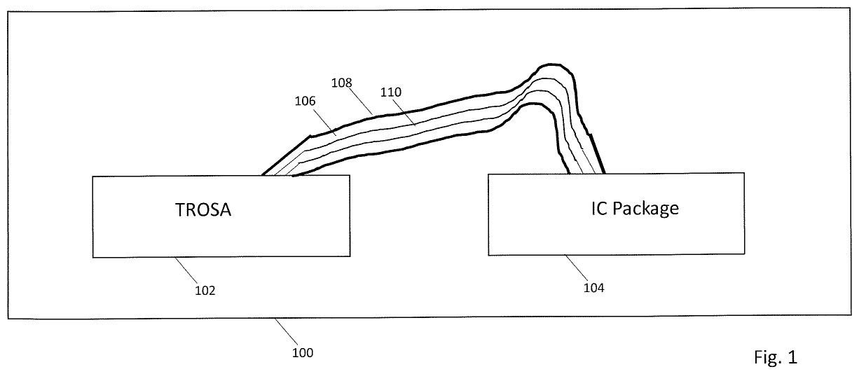

FIG. 1 shows an example of a transceiver module 100 consistent with an aspect of the present disclosure. Transceiver modules 100 includes TROSA 102 that supplies modulated optical signals to a first fiber (not shown) and receives optical signals from a second fiber (note shown). An IC package 104 provides electrical signals to and receives electrical signals from TROSA 102 by way of flexible interconnect 108, which includes traces or conductors 110 provided on a flexible film or thin substrate including a resin, such as a polyimide.

In the following figures, certain features of IC package 104 are common to the features shown in FIG. 1. However, corresponding reference characters associated with the such features have been omitted in the following figures for ease of illustration.

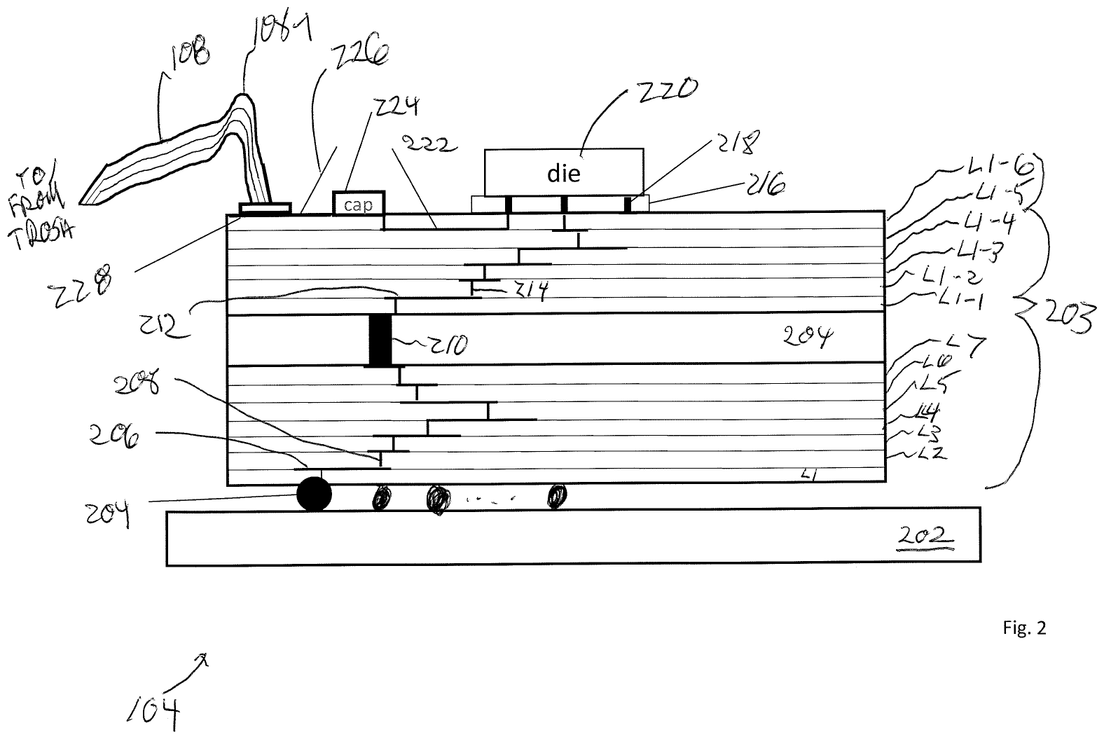

FIG. 2 shows a detailed cross-sectional view of IC package 104. IC package 104 includes a printed circuit board 202, which is attached to substrate 203 by a ball grid array 204 including a plurality of solder or conductive balls. Substrate 203 includes dielectric layers L1 to L7 and dielectric layer L1-1 separated from one another by core layer 204. A die or IC is provided on a topmost layer L1-6. Electrical conductors, such as 206, are provided between successive dielectric layer, such as conductor 206 between layers L1 and L2, and conductor 212 between layers L1-1 and L1-2. Conductive vias such as 206 and 214 provide an electrical connection between the traces or conductors. The conductors may include copper, for example. In addition, a core layer 204 may be provided in the middle of substrate 203, which along with the other layers of printed circuit board 203 may include a dielectric, such as a glass fiber filled resin.

IC 220 may be connected to substrate 203 by way of conductors or bumps 216. An underfill layer 216 may also be included to provide mechanical stability to bumps 216. First electrical connections may be made to the die by way of the ball grid array 204 and the conductors and conductive vias, including conductive vias 210 extending through core layer 204, that extend through the various layers of substrate 203 and the conductors or traces between each layer of substrate 203. Underfill layer may include a resin or epoxy.

It is understood that additional conductors, conductive vias, and bumps may be provided in and on substrate 203 to provide first electrical connections to the IC or die 220.

In order to facilitate high speed electrical connections between integrated circuit 220 and TROSA 102, electrical signals supplied by flexible interconnect 108 reach integrated circuit 220 by way of an electrical path including an RF connector or pad 228, controlled impedance line 226, DC blocking capacitor 224, and controlled impedance line 222. Controlled impedance lines 222 and 226 each include a transmission line (e.g., a stripline transmission line, microstrip line, T line, embedded microstrip line, and embedded strip line) and each may be provided either on the surface of substrate 203 or embedded in substrate 203, for example, near the surface of substrate 203.

Due to the flexible nature of the interconnect 108 including loop 108-1, the solder joint at pad 228 is mechanically decoupled from other features in package 110 in such a way that back and forth and lateral stresses placed on pad 228 during soldering are significantly reduced.

In the example shown in FIG. 1, the layers of substrate 203 may be made of a ceramic to provide sufficient rigidity and stiffness so as to limit thermally induced warping of the substrate when the IC attains an elevated temperature during operation.

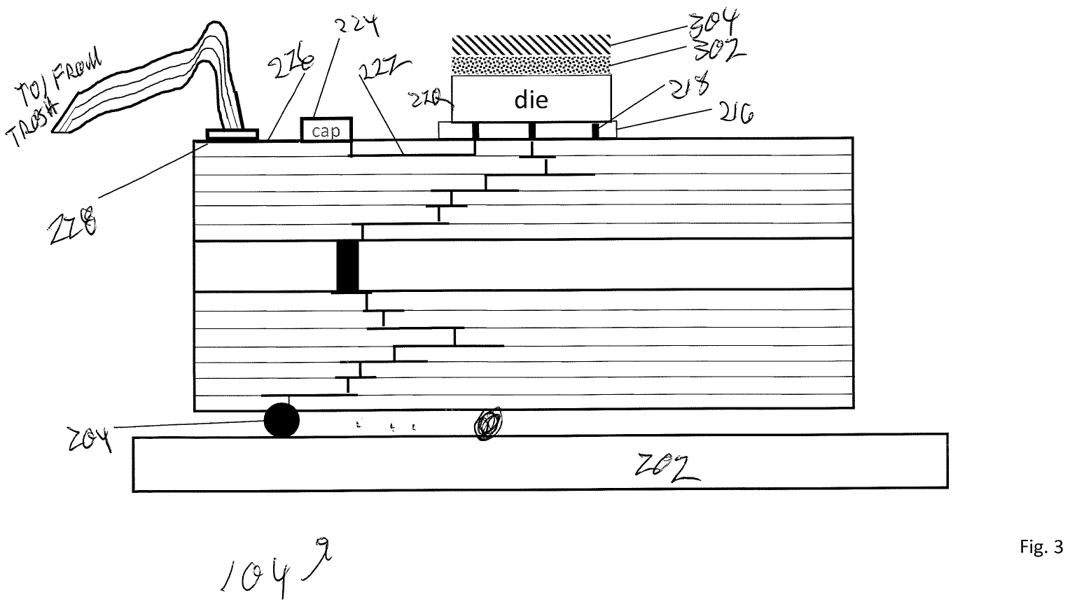

FIG. 3 shows an example of IC package 104 similar to that shown in FIG. 1. In the example shown in FIG. 3, however, a thermal interface material 302 is provided between the IC 302 and a heat spreader or lid 304, which may include copper or aluminum silicon carbide (AlSiC). Thermal interface material 302 may include an organic material having thermally conductive particles embedded therein such as aluminum oxide particles or metallic particles, such as silver. The thermal interface material 302 may alternatively include a grease, or boron nitride or silicone embedded with thermally conductive particles.

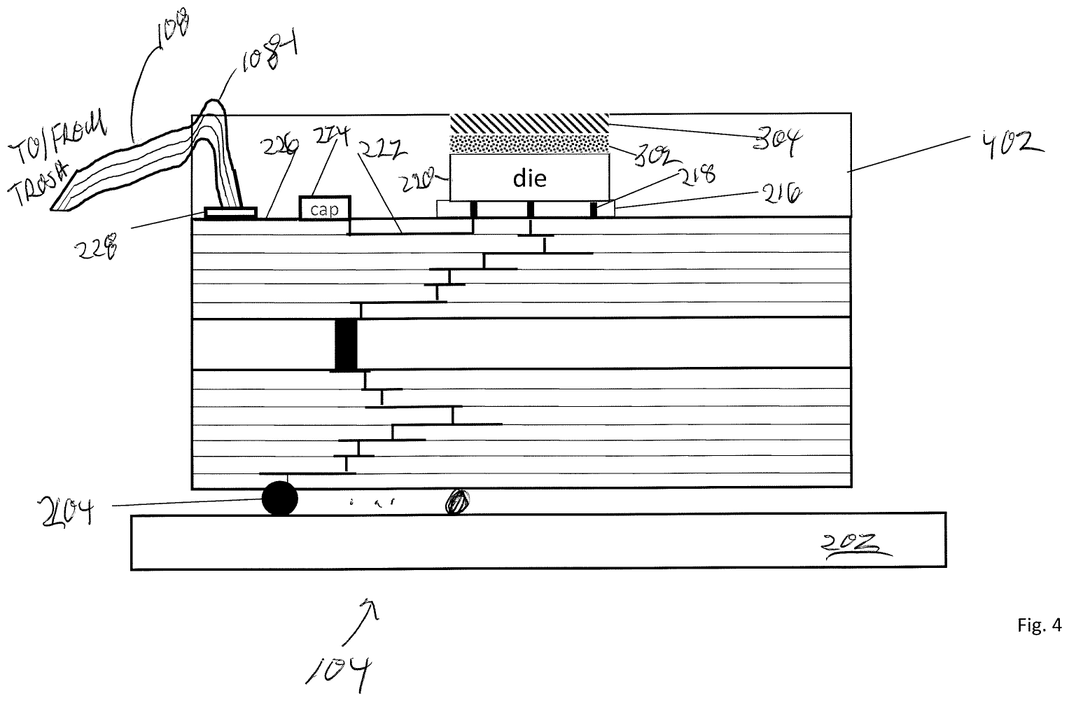

FIG. 4 shows a further example of the present disclosure which is similar to the example shown in FIG. 3, except mold compound 402 is provided over an entire surface of substrate 203. Mold compound 402 preferably has a stiffness and thermal expansion coefficient that exceeds that of IC or die 220. A thickness, as well as the thermal expansion coefficient and stiffness, of mold compound 404 is selected such that heat generated by IC 220 during operation generates stresses in substrate 203 that effectively cancel each other out or offset one another. It is noted that in the absence of mold compound 402, in this example, substrate 203 would be mechanically unbalanced between an asymmetry in the structure of substrate 203 due to the presence of the controlled impedance lines 222 and 226. Namely, in order to maintain a desired impedance of the controlled impedance line, a portion of substrate 203 adjacent these impedance lines is typically devoid of conductive vias or conductive traces, such as trace 212 noted above. As a result, the substrate may be stressed due to the asymmetry noted above at elevated temperatures created by IC 220, and such stresses may cause the substrate to lose its planarity resulting in potential damage to IC 220 and/or bumps 218.

It is noted, that, in one example, a cut-out portion is provided in mold compound 402 to accommodate the connection of the interconnect 108 to pad 228. The cut-out is relatively small and does not sufficiently affect the ability of mold compound 402 to maintain the planarity of substrate 203.

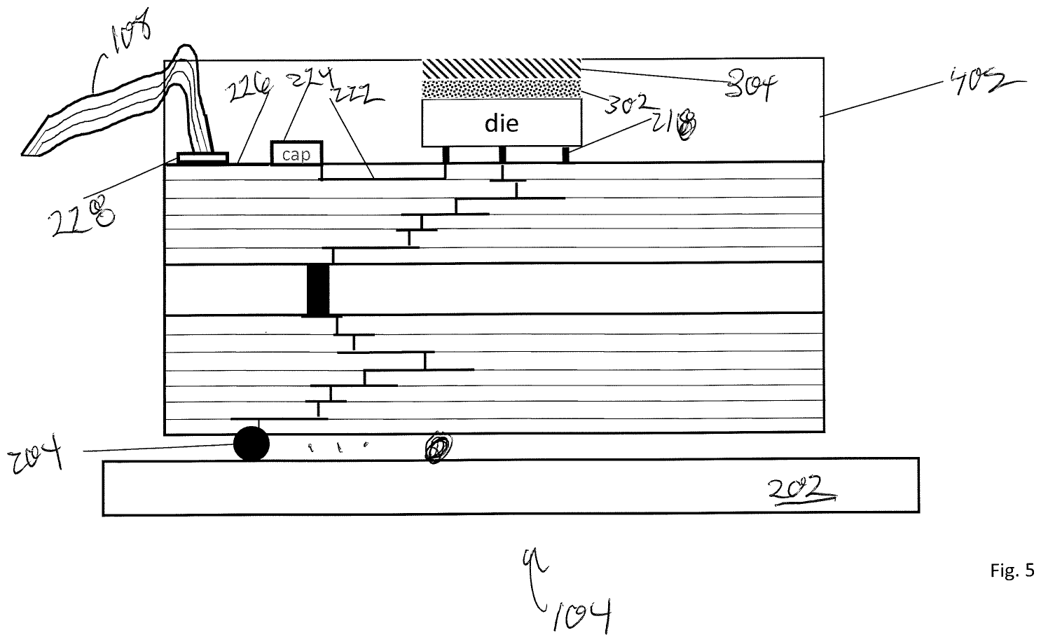

The example shown in FIG. 5 is similar to the example shown in FIG. 4 except that underfill 216 is omitted. Instead, mold compound 402 extends beneath IC or die 220 to provide mechanical stability to bumps 218.

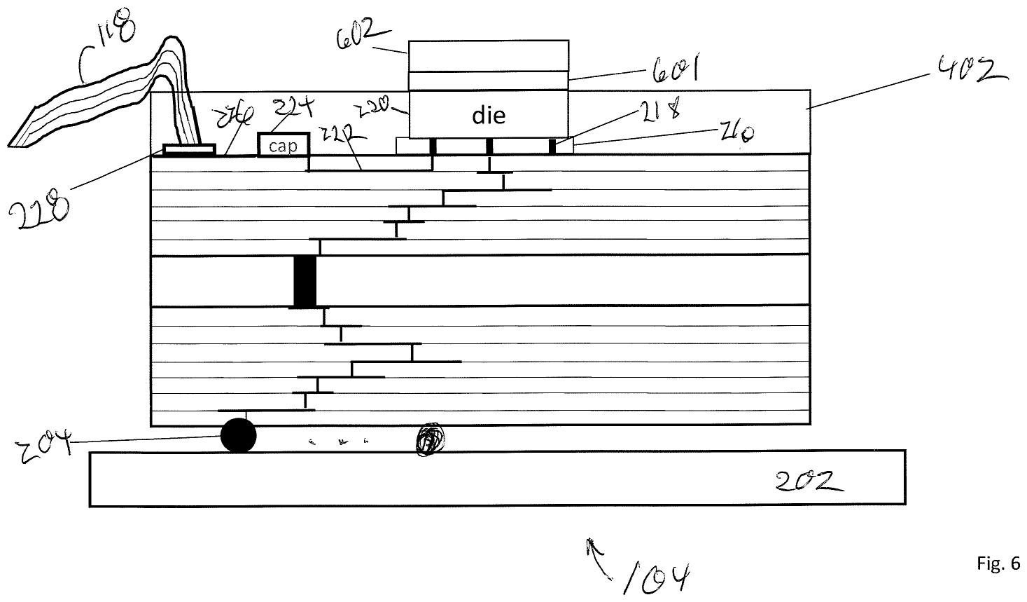

In FIG. 6, mold compound layer 402 has a reduced thickness to thereby expose a top surface of IC or die 220. As a result, thermal interface layer 601, similar to that described above, may be provided directly on a top surface of IC or die 220, and a heat sink 602 may be provided on layer 601, thereby obviating layers 302 and 304 which would otherwise be provided between die 220 and the heat sink if mold compound layer 402 were thicker, as in FIG. 5.

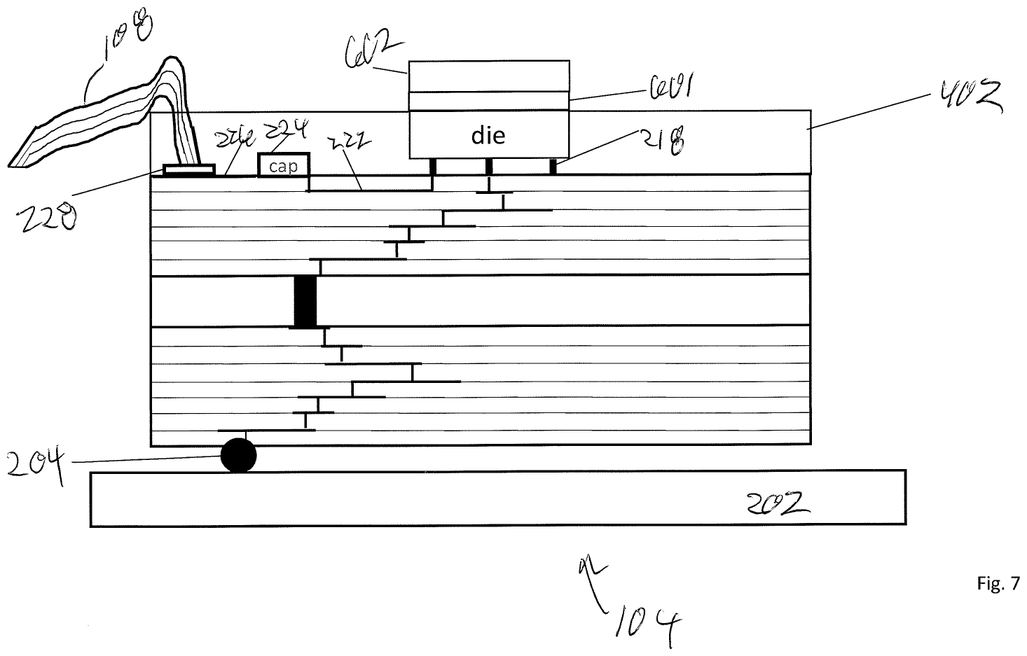

FIG. 7 shows an example similar to that shown in FIG. 6 with the exception that underfill layer 216 is omitted and mold compound layer 402 extends beneath die 220 to provide mechanical support for bumps 218 in a manner similar to that described above with respect to FIG. 5.

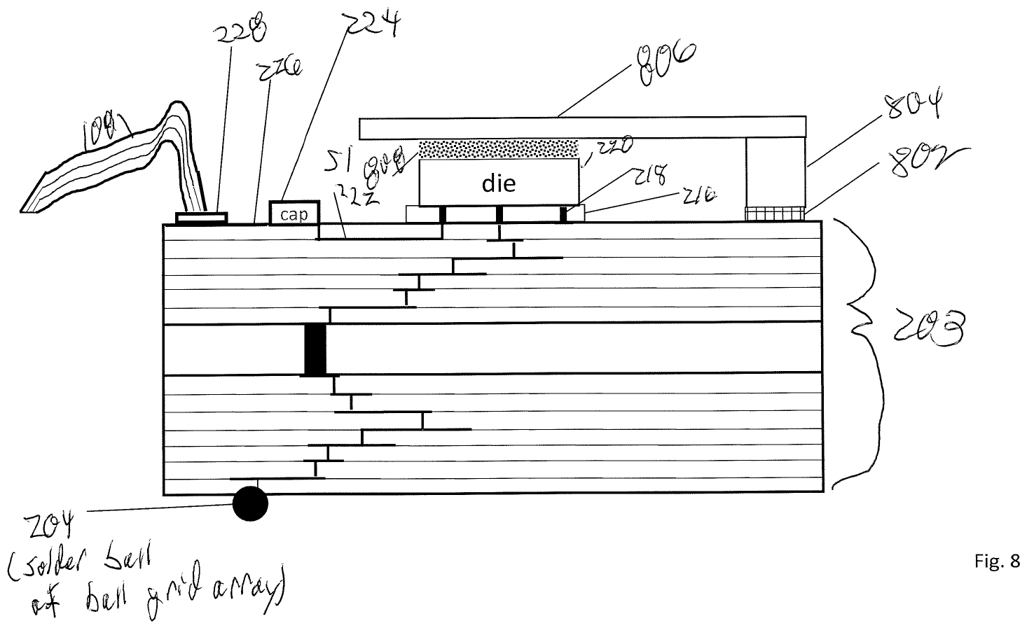

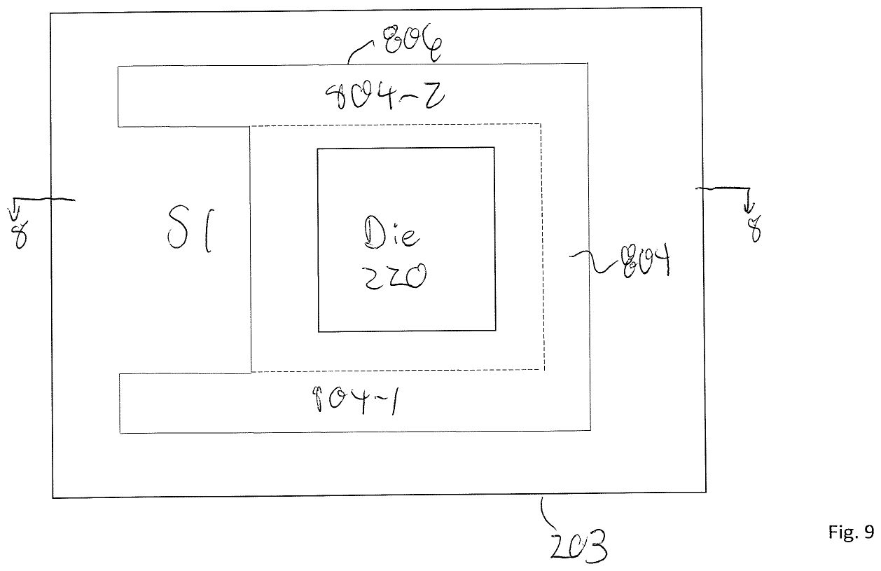

The next example will next be described with reference to FIGS. 8 and 9. FIG. 8 show a cross-sectional view (taken along 8-8 in FIG. 9) in which mold compound layer 402 is omitted. Here, a lid 806, including a conductor, such as copper, is attached to die 220 by a thermal interface material 808. Moreover, lid 806 is attached substrate 203 by a wall, which may also be made of a conductive material, such as copper, bonded to substrate 203 by a joint 802, including solder, for example, or a conductive adhesive material.

In a further example, lid 806 is attached by walls 804-1 and 804-2 in addition to or instead of wall 804. Walls 804-1 and 804-2, as well as wall 804, may be made of the same material as lid 806 or another conductive material. It is noted that, in this example, that a gap is provided between lid 806 and substrate 203, such that one side of lid 806 is detached from substrate 203. Accordingly, a side of die 220 adjacent region S1 is open so that die 220 is not enclosed on all sides. In addition, walls 80-4-1 and 804-2 may make connections to substrate 203 on substrate sides that are perpendicular to the RF axis.

Lid 806 in combination with walls 804 on the surface of substrate 203 causes thermally induced stresses to counteract one another such that the substrate remains substantially planar. A similar result may be achieved as noted above with respect to mold compound 402.

Other embodiments will be apparent to those skilled in the art from consideration of the specification. It is intended that the specification and examples be considered as exemplary only, with a true scope and spirit of the invention being indicated by the following claims.

What is claimed is:

1. An integrated circuit package, including:
a substrate;
a die provided on the substrate;
a pad provided on the substrate;
a controlled impedance line connecting the pad to the die; and
a mold compound layer provided on the surface of the substrate that is operable to compensate thermally induced stresses in the substrate during operation of the die.

2. An integrated circuit package in accordance with claim 1, further including a flexible interconnect attached to the pad.

3. An integrated circuit package including:
a substrate;
a die provided on the substrate;
a pad provided on the substrate;
a controlled impedance line connecting the pad to the die; and
a wall made of conductive material provided on the surface of the substrate and a lid extending over the die and attached to substrate by the wall, such that that the wall and lid are operable to compensate thermally induced stresses in the substrate during operation of the die.
